(19) United States
(12) Patent Application Publication
(10) Pub. No.: US 2025/0253278 A1
(43) Pub. Date: Aug. 7, 2025

(54) SEMICONDUCTOR DEVICES, FABRICATION METHODS THEREOF, AND MEMORY SYSTEMS

(71) Applicant: YANGTZE MEMORY TECHNOLOGIES CO., LTD., Wuhan (CN)

(72) Inventors: Dongyu FAN, Wuhan (CN); Hao ZHENG, Wuhan (CN); Tingting GAO, Wuhan (CN); Yuxuan FANG, Wuhan (CN); Lei LIU, Wuhan (CN); ZhiLiang XIA, Wuhan (CN)

(21) Appl. No.: 18/767,733

(22) Filed: Jul. 9, 2024

(30) Foreign Application Priority Data
Feb. 6, 2024 (CN) 2024101714286

(51) Int. Cl. H01L 23/00; H01L 23/48; H01L 25/065; H10B 80/00

(52) U.S. Cl. CPC H01L 24/29; H01L 23/481; H01L 24/27; H01L 24/32; H10B 80/00; H01L 25/0657; H01L 2224/27452; H01L 2224/29005; H01L 2224/29084; H01L 2224/29187; H01L 2224/29387; H01L 2224/29541; H01L 2224/2958; H01L 2224/29687; H01L 2224/32145; H01L 2225/06541; H01L 2924/1436

(57) ABSTRACT

Semiconductor devices, fabrication methods thereof and memory systems are provided. In one aspect, a semiconductor device includes chips and a bonding dielectric layer. The chips are stacked along a thickness direction of the chips. The bonding dielectric layer is located between two adjacent ones of the chips. The bonding dielectric layer at least includes a first material and a second material, and thermal conductivity of the second material is greater than thermal conductivity of the first material.

### CROSS-REFERENCE TO RELATED APPLICATIONS

The present application claims priority to Chinese Patent Application No. 2024101714286, which was filed Feb. 6, 2024, is titled “SEMICONDUCTOR DEVICE AND ITS PREPARATION METHOD, STORAGE SYSTEM,” and is hereby incorporated herein by reference in its entirety.

### TECHNICAL FIELD

The present disclosure relates to semiconductors, and, in particular, to semiconductor devices, fabrication methods thereof, and memory systems.

### BACKGROUND

With the continuous development of technologies in the semiconductor industry, the number of chips in a semiconductor device continues to increase. Heat generated by a plurality of chips is difficult to diffuse and conduct to the outside.

### SUMMARY

In an aspect, some examples of the present disclosure provide a semiconductor device. The semiconductor device may include: a plurality of chips and at least one bonding dielectric. The plurality of chips are stacked along a thickness direction of the chips. The bonding dielectric layer is located between two adjacent ones of the chips. The bonding dielectric layer at least may include a first material and a second material, and thermal conductivity of the second material is greater than thermal conductivity of the first material.

In some examples, the bonding dielectric layer extends along a direction perpendicular to the thickness direction of the chips.

In some examples, the bonding dielectric layer may include a plurality of first sublayers and a plurality of second sublayers alternately stacked along the thickness direction of the chips. The first sublayer may include the first material. The second sublayer may include the second material.

In some examples, in the bonding dielectric layer, each of the second sublayers is located between any two adjacent ones of the first sublayers.

In some examples, in the same bonding dielectric layer, a thickness of the first sublayer adjoining the chip is greater than or equal to a thickness of the second sublayer.

In some examples, in the same bonding dielectric layer, the thickness of the first sublayer located between two adjacent ones of the second sublayers is greater than or equal to the thickness of the first sublayer adjoining the chip.

In some examples, in the bonding dielectric layer, the first sublayer adjoining the chip is configured to achieve bonding between the chip and the second sublayer. The first sublayer located between the two adjacent ones of the second sublayers is configured to achieve bonding between two adjacent ones of the chips.

In some examples, a ratio of a sum of thicknesses of the plurality of second sublayers to a sum of thicknesses of the plurality of first sublayers is greater than or equal to 1:10, and less than or equal to 1:2.

In some examples, in the bonding dielectric layer, the second material is doped in the first material.

In some examples, the thermal conductivity of the second material is greater than or equal to 10 W/m*K.

In some examples, the first material may include a bonding material; and the second material may include a heat conduction material.

In some examples, the second material may include at least one of silicon nitride, aluminum oxide, and silicon carbide.

In some examples, the first material may include silicon oxide.

In some examples, the semiconductor device further may include a plurality of conductive pillars penetrating through the chips, and each of the plurality of conductive pillars is configured to connect two adjacent ones of the chips.

In some examples, the semiconductor device further may include a plurality of conductive pillars at least penetrating through two adjacent ones of the chips and the bonding dielectric layer between the two adjacent ones of the chips, and each of the plurality of conductive pillars is configured to connect the two adjacent ones of the chips.

In another aspect, a fabrication method of a semiconductor device is provided. The fabrication method may include: providing a plurality of chips comprising a first chip and a second chip; forming a bonding dielectric sublayer on the first chip and the second chip respectively, wherein the bonding dielectric sublayer at least may include a first material and a second material, and thermal conductivity of the second material is greater than thermal conductivity of the first material; and bonding the first chip with the second chip based on the bonding dielectric sublayer on the first chip and the bonding dielectric sublayer on the second chip.

In some examples, forming the bonding dielectric sublayer on the first chip and the second chip at least may include: forming a first sublayer on each of the chips; forming a second sublayer on the first sublayer; and forming the first sublayer on the second sublayer.

In some examples, forming the bonding dielectric sublayer on the first chip and the second chip may include: forming the bonding dielectric sublayer on the first chip and the second chip using a plasma enhanced chemical vapor deposition process. In the bonding dielectric sublayer, the second material is doped in the first material.

In some examples, a reaction gas for forming the bonding dielectric sublayer may include silane, nitrogen, and nitrous oxide.

In yet another aspect, a memory system is provided. The memory system may include a semiconductor device. The semiconductor device may include: a plurality of chips and at least one bonding dielectric. The plurality of chips are stacked along a thickness direction of the chips. The bonding dielectric layer is located between two adjacent ones of the chips. The bonding dielectric layer at least may include a first material and a second material, and thermal conductivity of the second material is greater than thermal conductivity of the first material. The memory system may further include a controller coupled to the semiconductor device and configured to control the semiconductor device to store data.

### BRIEF DESCRIPTION OF THE DRAWINGS

In order to illustrate the technical solution in the present disclosure more clearly, the drawings to be used in some examples of the present disclosure will be briefly introduced below. Apparently, the drawings in the following description are only drawings of some examples of the present disclosure. Those of ordinary skills in the art may also obtain other drawings according to these drawings. In addition, the drawings in the following description may be regarded as schematic diagrams, instead of limitations on actual sizes of products, actual procedures of methods, etc. involved in the examples of the present disclosure.

FIG. 1 is a structural diagram of an electronic apparatus according to some examples of the present disclosure;

FIG. 2 is a structural diagram of a memory system according to some examples of the present disclosure;

FIG. 3 is a structural diagram of a semiconductor device according to some examples of the present disclosure;

FIG. 4 is a structural diagram of another semiconductor device according to some examples of the present disclosure;

FIG. 5 is a structural diagram of yet another semiconductor device according to some examples of the present disclosure;

FIG. 6 is a structural diagram of still another semiconductor device according to some examples of the present disclosure;

FIG. 7 is a structural diagram of still another semiconductor device according to some examples of the present disclosure;

FIG. 8 is a flow diagram of a fabrication method of a semiconductor device according to some examples of the present disclosure;

FIGS. 9-13 are structural diagrams corresponding to various operations of a fabrication method of a semiconductor device according to some examples of the present disclosure;

FIGS. 14A, 14B, and 14C are a flow diagram of a fabrication method of another semiconductor device according to some examples of the present disclosure; and

FIG. 15 is a simple structural diagram of a plasma chemical vapor deposition apparatus according to some examples of the present disclosure.

### DETAILED DESCRIPTION

The technical solutions in some examples of the present disclosure will be described below clearly and completely in conjunction with the drawings. Apparently, the examples described are only part of, but not all of, the examples of the present disclosure. All other examples obtained by those of ordinary skills in the art based on the examples provided by the present disclosure should fall in the scope of protection of the present disclosure.

In the description of the present disclosure, the terms “center”, “upper”, “lower”, “horizontal”, “inside”, etc. indicate orientations or position relationships that are based on the orientations or position relationships as shown in the drawings, and are only intended to facilitate description of the present disclosure and to simplify the description, instead of indicating or implying that a device or an element indicated must have a specific orientation or be constructed and operated in a specific orientation, and thus cannot be understood as limiting the present disclosure.

Unless otherwise specified in the context, throughout the specification and the claims, the term “comprise” is interpreted as an open and inclusive meaning, e.g., “including, but not limited to”. In the description of the specification, the terms “one embodiment”, “some embodiments”, “example embodiment”, “exemplarily” or “some examples”, etc. are intended to indicate that particular features, structures, materials, or characteristics related to the example are included in at least one example of the present disclosure. The schematic representation of the above terms may not necessarily refer to the same embodiment or example. Furthermore, these particular features, structures, materials, or characteristics may be included in any of one or more embodiments or examples in any suitable manner.

In the following, the terms “first” and “second” are only for the purpose of description, and cannot be construed as indicating or implying relative importance or implicitly indicating the number of indicated technical features. Thus, features defined by “first” and “second” may explicitly or implicitly comprise one or more of such features. In the description of the examples of the present disclosure, “a plurality of” means two or more, unless otherwise stated.

In describing some examples, expressions of “connected” and derivatives thereof may be used. For example, the term “connected” may be used in the description of some examples to indicate that two or more components have a direct physical contact or an electrical contact with each other.

Example implementations are described herein with reference to a cross-sectional view and/or a planar view that are used as idealized example drawings. In the drawings, thicknesses of layers and areas of regions are exaggerated for clarity. Thus, changes in shapes relative to the drawings caused by, for example, manufacturing technology and/or tolerance, may be contemplated. The example implementations should not be interpreted as limitations on the shapes of regions shown herein, but rather comprise shape deviations caused by, for example, manufacturing. For example, an etching region shown as a rectangle will typically have a curved feature. The regions shown in the drawings are essentially schematic, and their shapes are neither intended to show actual shapes of regions of an apparatus, nor intended to limit the scope of the example implementations.

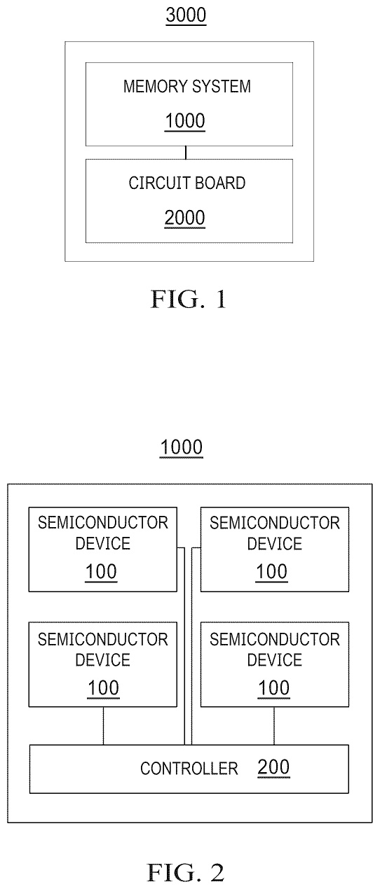

As shown in FIG. 1, some examples of the present disclosure provide an electronic apparatus 3000, which may comprise any apparatus capable of storing data, such as a mobile phone, a desktop computer, a tablet computer, a notebook computer, a server, etc. The electronic apparatus 3000 may comprise a memory system 1000 configured to implement data storage as described below, and a circuit board 2000 electrically connected with the memory system. The circuit board 2000 is configured to provide electrical signals, etc., to the memory system 1000.

As shown in FIG. 2, some examples of the present disclosure provide a memory system 1000. The memory system 1000 is used in the above-mentioned electronic apparatus 3000. The memory system 1000 comprises a semiconductor device 100 and a controller 200. The controller 200 is coupled with the semiconductor device 100, and is configured to control the semiconductor device 100 to store data.

The memory system 1000 may be integrated into various types of storage apparatuses, for example, be included in the same package, such as a universal flash storage (UFS for short) package or an embedded multimedia card (eMMC for short) package. That is to say, the memory system 1000 may be applied to and packaged into different types of electronic products, such as a mobile phone, a desktop computer, a laptop computer, a tablet computer, a vehicle computer, a game console, a printer, a positioning apparatus, a wearable electronic apparatus, a smart sensor, a Virtual Reality (VR for short) apparatus, an Augmented Reality (AR for short) apparatus, or any other electronic apparatuses with memories.

In some examples, the memory system 1000 comprises a controller 200 and one semiconductor device 100, wherein the memory system 1000 may be, for example, integrated into a memory card. The above-mentioned memory card comprises one of a PC (PCMCIA, Personal Computer Memory Card International Association) card, a compact flash (CF for short) card, a smart media (SM for short) card, a memory stick, a multimedia card (MMC for short), a secure digital memory card (SD for short) card, and a UFS.

In some other examples, as shown in FIG. 2, the memory system 1000 comprises a controller 200 and a plurality of semiconductor devices 100.

In an example, the memory system 1000 comprises a controller 200 and four semiconductor devices 100. The memory system 1000 may be, for example, integrated into solid state drives (SDDs for short).

In some examples, in the memory system 1000, the controller 200 is configured to operate in a low duty-cycle environment, such as an SD card, a CF card, a universal serial bus (USB for short) flash drive, or other media for use in electronic apparatuses, such as a personal computer, a digital camera, a mobile phone, etc.

In some other examples, in the memory system 1000, the controller 200 is configured to operate in high duty-cycle environment SSDs or eMMCs used as data memories for mobile apparatuses, such as smartphones, tablet computers, laptop computers, etc., and enterprise memory arrays.

In some examples, the controller 200 may be configured to manage data stored in the semiconductor devices 100 and communicate with an external apparatus (e.g., a host).

In some examples, the controller 200 may be further configured to control operations of the semiconductor devices 100, such as read, erase, and program operations.

In some examples, the controller 200 may be further configured to manage various functions with respect to data stored or to be stored in the semiconductor devices 100, including at least one of bad-block management, garbage collection, logical-to-physical address conversion, and wear leveling.

In some examples, the controller 200 is further configured to process error correction codes with respect to the data read from or written to the semiconductor devices 100.

The controller 200 may also perform any other suitable functions, such as formatting the semiconductor devices 100. For another example, the controller 200 may communicate with an external apparatus (e.g., a host) through at least one of various interface protocols.

The interface protocols include at least one of a USB protocol, an MMC protocol, a peripheral component interconnection (PCI) protocol, a PCI-express (PCI-E) protocol, an Advanced Technology Attachment (ATA) protocol, a serial-ATA protocol, a parallel-ATA protocol, a Small Computer Small Interface (SCSI) protocol, an Enhanced Small Disk Interface (ESDI) protocol, an Integrated Drive Electronics (IDE) protocol, and a Firewire protocol.

The above-mentioned controller 200 may be, for example, a central processing unit (CPU), a general-purpose processor, a digital signal processor (DSP), an application-specific integrated circuit (ASIC), a field programmable gate array (FPGA), or other programmable logic devices, transistor logic devices, hardware components, or any combination thereof.

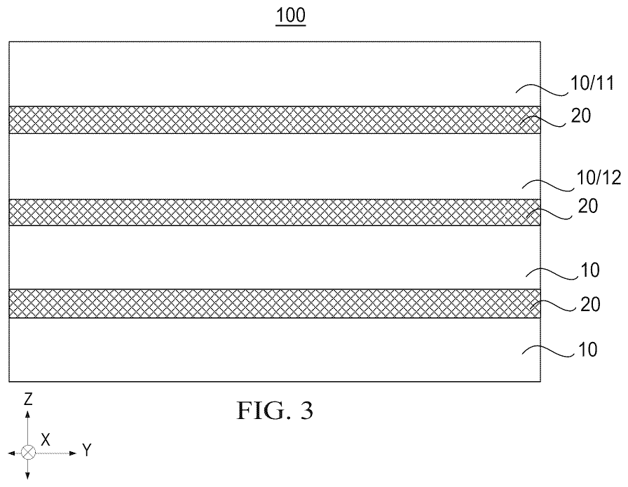

As shown in FIG. 3, some examples of the present disclosure provide a semiconductor device 100, which may be used in the memory system in the above-mentioned examples. The semiconductor device 100 comprises a plurality of chips 10 and at least one bonding dielectric layer 20.

The plurality of chips 10 above-mentioned are stacked along a thickness direction of the chips 10.

In FIG. 3, X represents a first direction, Y represents a second direction, and Z represents a third direction. The third direction Z is the thickness direction of the chips 10, and both the first direction X and the second direction Y are perpendicular to the third direction Z. There is an included angle between the first direction X and the second direction Y, which may be 90°.

For example, the above-mentioned semiconductor device 100 may be a DRAM (Dynamic Random Access Memory), a CIS (Complementary Metal-Oxide-Semiconductor Transistor Image Sensor), an HMC (Hybrid Memory Cube), etc.

The above-mentioned at least one bonding dielectric layer 20 is located between two adjacent ones of the chips 10. The two adjacent ones of the chips 10 are bonded via the bonding dielectric layer 20.

For example, among the plurality of chips 10 of the semiconductor device 100, the above-mentioned bonding dielectric layer 20 is disposed between every two adjacent ones of the chips 10.

For another example, among a part of the chips 10 of the plurality of chips 10 of the semiconductor device 100, the above-mentioned bonding dielectric layer 20 is disposed between every two adjacent chips 10; and among the other part of the chips 10, another film layer is disposed between every two adjacent chips 10, and is configured to achieve bonding between the chips 10.

The above-mentioned bonding dielectric layer 20 at least comprises a first material and a second material. The first material is configured to achieve bonding between the chips 10. During operation of the semiconductor device 100, heat generation is inevitable. The above-mentioned second material is configured to achieve heat dissipation between the chips 10, and thermal conductivity of the second material is greater than thermal conductivity of the first material. Heat dissipation of the semiconductor device 100 can be improved, thereby avoiding affecting performance of the semiconductor device 100 due to heat accumulation inside the chips 10.

The bonding dielectric layer 20 may further comprise other materials than the first material and the second material.

According to the semiconductor device 100 provided by the examples of the present disclosure, the semiconductor device 100 comprises the plurality of chips 10 stacked along the thickness direction and the bonding dielectric layer 20 located between the two adjacent ones of the chips 10, the bonding dielectric layer 20 comprises the first material and the second material, and the thermal conductivity of the second material is greater than the thermal conductivity of the first material, such that the thermal conductivity of the bonding dielectric layer 20 is high, the heat between the two adjacent ones of the chips 10 can be diffused and conducted to the outside in time, and the heat dissipation of the semiconductor device 100 is improved, thereby avoiding affecting the performance of the semiconductor device 100 due to the heat accumulation inside the chips 10.

Sizes of the plurality of chips 10 in the semiconductor device 100 may be equal or unequal. The following is an illustrative example where the sizes of the plurality of chips 10 are equal, and orthographic projections of the chips 10 on a plane where the bonding dielectric layer 20 is located overlap with each another.

There are various structures for the bonding dielectric layer 20, which can be set according to actual needs, and are not limited by the examples of the present disclosure.

In an example, as shown in FIG. 3, the bonding dielectric layer 20 extends along a direction perpendicular to the thickness direction of the chips 10.

For example, the above-mentioned two chips 10 comprise a first chip 11 and a second chip 12. The first chip 11 is located on the second chip 12, and the bonding dielectric layer 20 is located between the first chip 11 and the second chip 12, and covers a surface of a side of the second chip 12 close to the first chip 11. Alternatively, an orthographic projection of the bonding dielectric layer 20 on a plane where the second chip 12 is located overlaps with an orthographic projection of the first chip 11 on the plane where the second chip 12 is located.

Part of the heat can be transferred and diffused to the corresponding bonding dielectric layers 20 from the chip 10, such that the heat may not only be transferred and diffused in a longitudinal direction (the longitudinal direction may be referred to the third direction Z in FIG. 3) between the two adjacent ones of the chips 10, but also be transferred and diffused in a lateral direction (the lateral direction may be referred to the first direction X and the second direction Y in FIG. 3) through the bonding dielectric layer 20, thereby increasing the number of dissipation paths for the heat, and further improving the heat dissipation capability of the semiconductor device 100.

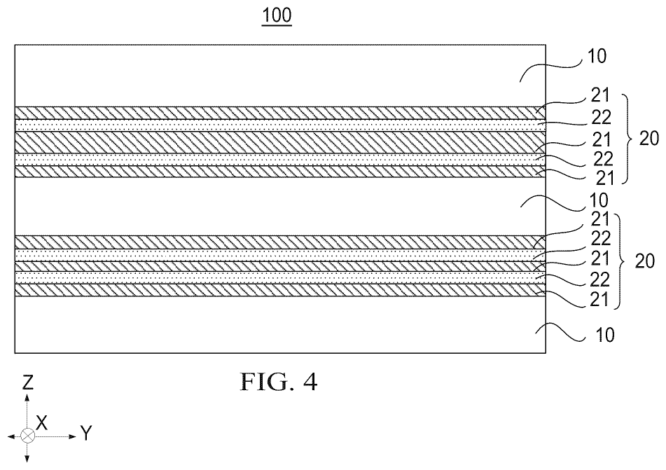

In some examples, as shown in FIG. 4, the bonding dielectric layer 20 comprises a plurality of first sublayers 21 and a plurality of second sublayers 22 alternately stacked along the thickness direction of the chip 10.

For example, along the thickness direction of the chip 10, the first sublayer 21, the second sublayer 22, the first sublayer 21, the second sublayer 22, etc. are sequentially stacked.

For example, the plurality of first sublayers 21 described above are aligned with the plurality of second sublayers 22 along the thickness direction of the chip 10. Alternatively, orthographic projections of the plurality of first sublayers 21 and the plurality of second sublayers 22 on a plane where one chip 10 is located overlap.

The first sublayer 21 comprises the above-mentioned first material. The second sublayer 22 comprises the above-mentioned second material.

The first sublayer 21 comprising the first material can achieve the bonding between the two adjacent ones of the chips 10, and the second sublayer 22 comprising the second material is used to improve the heat dissipation capability of the bonding dielectric layer 20 and the semiconductor device 100. Moreover, the second sublayer 22 comprising the second material is disposed as a whole layer, such that thermal conductivities at different positions between the two adjacent ones of the chips 10 tend to be approximately uniform, which is beneficial to improving the heat dissipation capability of the chips 10 and the semiconductor device 100.

In an example, as shown in FIG. 4, in the above-mentioned bonding dielectric layer 20, each second sublayer 22 is located between any two adjacent ones of the first sublayers 21.

For example, the bonding dielectric layer 20 may comprise the first sublayer 21, the second sublayer 22, the first sublayer 21, the second sublayer 22, and the first sublayer 21 sequentially stacked on the chip 10.

The first sublayer 21 in the bonding dielectric layer 20 adjoins or contacts with the chip 10, which may ensure bonding strength between the chip 10 and the bonding dielectric layer 20, and the second sublayer 22 may also be utilized to improve the heat dissipation of the semiconductor device 100.

In an example, in the bonding dielectric layer 20, the first sublayer 21 located between the chip 10 and the second sublayer 22 is configured to achieve bonding between the chip 10 and the second sublayer 22; and the first sublayer 21 located between the two adjacent ones of the second sublayers 22 is bonded with the chip 10 by connecting the first sublayer 21 with the adjacent second sublayer 22 and the chip 10, thereby achieving the bonding between the two adjacent ones of the chips 10. The bonding strength between the second sublayer 22 and the chip 10 is high, and the bonding strength between the two chips 10 is high, thereby ensuring the bonding strength between the chips 10.

In the same bonding dielectric layer 20, thicknesses of the first sublayers 21 may be equal or unequal; and thicknesses of the first sublayer 21 and the second sublayer 22 may be equal or unequal. Thicknesses of the first sublayers 21 in different bonding dielectric layers 20 may be equal or unequal; and thicknesses of the second sublayers 22 in different bonding dielectric layers 20 may be equal or unequal.

As shown in FIG. 4, in the same bonding dielectric layer 20, the thickness of the first sublayer 21 adjoining the chip 10 is greater than or equal to the thickness of the second sublayer 22.

For example, in the bonding dielectric layer 20, the thickness of the first sublayer 21 adjoining the chip 10 is greater than the thickness of the second sublayer 22. The bonding strength of the first sublayer 21 to the chip 10 and the second sublayer 22 adjacent to the first sublayer 21 can be ensured, and a sum of the thicknesses of the plurality of first sublayers 21 in the bonding dielectric layer 20 is large, such that the first sublayers 21 have a high proportion (e.g., a mass ratio) in the bonding dielectric layer 20, which may ensure a certain bonding strength between adjacent chips 10.

For another example, the thickness of the first sublayer 21 adjoining the chip 10 is equal to the thickness of the second sublayer 22. A proportion (e.g., a mass ratio) of the second sublayers 22 in the bonding dielectric layer 20 can be increased, and the heat dissipation capability of the semiconductor device 100 can be improved.

As shown in FIG. 4, in the same bonding dielectric layer 20, the thickness of the first sublayer 21 located between the two adjacent ones of the second sublayers 22 is greater than or equal to the thickness of the first sublayer 21 adjoining the chip 10.

For example, in the bonding dielectric layer 20, the thickness of the first sublayer 21 located between the two adjacent ones of the second sublayers 22 is greater than the thickness of the first sublayer 21 adjoining the chip 10.

As can be seen from the above, the first sublayer 21 located between the two adjacent ones of the second sublayers 22 is configured to achieve the bonding between the two adjacent ones of the chips 10. The above arrangement can ensure the bonding strength of the chips 10, and the sum of the thicknesses of the plurality of first sublayers 21 in the bonding dielectric layer 20 may be also large, such that the proportion (e.g., the mass ratio) of the first sublayers 21 in the bonding dielectric layer 20 is high, thereby further ensuring a certain bonding strength between the adjacent chips 10.

For another example, the thickness of the first sublayer 21 located between the two adjacent ones of the second sublayers 22 is equal to the thickness of the first sublayer 21 adjoining the chip 10.

The above arrangement is further beneficial to increasing the proportion (e.g., the mass ratio) of the second sublayers 22 in the bonding dielectric layer 20, and improving the heat dissipation capability of the semiconductor device 100.

In an example, a ratio of the sum of the thicknesses of the plurality of second sublayers 22 to the sum of the thicknesses of the plurality of first sublayers 21 is greater than or equal to 1:10, and less than or equal to 1:2.

For example, in the same bonding dielectric layer 20, the ratio of the sum of the thicknesses of the plurality of second sublayers 22 to the sum of the thicknesses of the plurality of first sublayers 21 is greater than or equal to 1:10, and less than or equal to 1:7; or greater than or equal to 1:7, and less than or equal to 1:5; or greater than or equal to 1:6, and less than or equal to 1:4; or greater than or equal to 1:8, and less than or equal to 1:2.

For example, in the same bonding dielectric layer 20, the ratio of the sum of the thicknesses of the plurality of second sublayers 22 to the sum of the thicknesses of the plurality of first sublayers 21 is 1:10, 1:9, 1:7, 1:6, 1:3, or 1:2.

The ratio of the sum of the thicknesses of the plurality of second sublayers 22 to the sum of the thicknesses of the plurality of first sublayers 21 in the bonding dielectric layer 20 can be within a reasonable range, thereby ensuring an increase in the overall average thermal conductivity of the bonding dielectric layer 20 while ensuring the bonding strength of the semiconductor device 100.

Among the plurality of bonding dielectric layers 20 of the semiconductor device 100, the ratio of the sum of the thicknesses of the plurality of second sublayers 22 to the sum of the thicknesses of the plurality of first sublayers 21 in one bonding dielectric layer 20 has a range of G; and the ratio of the sum of the thicknesses of the plurality of second sublayers 22 to the sum of the thicknesses of the plurality of first sublayers 21 in another bonding dielectric layer 20 has a range of H, and above-mentioned G may be the same as or different from H. The ratio of the sum of the thicknesses of the plurality of second sublayers 22 to the sum of the thicknesses of the plurality of first sublayers 21 in one bonding dielectric layer 20 is G1, the ratio of the sum of the thicknesses of the plurality of second sublayers 22 to the sum of the thicknesses of the plurality of first sublayers 21 in another bonding dielectric layer 20 is G2, and above-mentioned G1 and G2 may be equal or unequal. The examples of the present disclosure do not impose limitations in this regard, and the arrangement can be made according to actual needs.

For example, in the semiconductor device 100, the ratio of the sum of the thicknesses of the plurality of second sublayers 22 to the sum of the thicknesses of the plurality of first sublayers 21 has a range of 1:10-1:7, 1:7-1:5, 1:6-1:4, or 1:8-1:2.

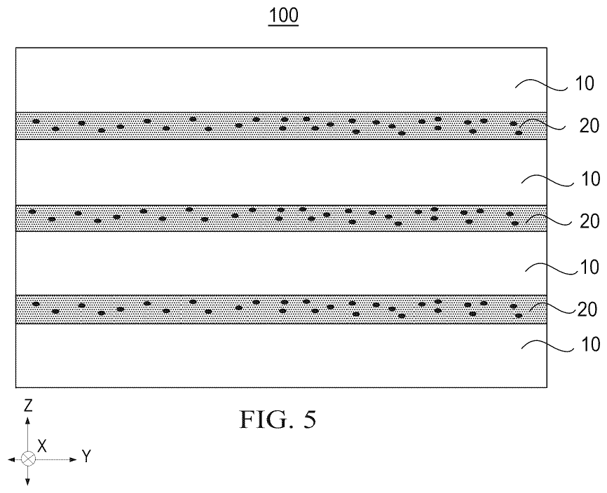

In some other examples, as shown in FIG. 5, in the bonding dielectric layer 20, the second material is doped in the first material.

For example, a mass ratio of the second material in the bonding dielectric layer 20 is less than a mass ratio of the first material in the bonding dielectric layer 20.

For example, the second material is uniformly doped in the first material to form the above-mentioned bonding dielectric layer 20.

By means of the above arrangement, the second material with the high thermal conductivity is doped in the first material, such that the thermal conductivity of the bonding dielectric layer 20 constituted by the first material and the second material is increased, the heat dissipation capability of the chip 10 and the semiconductor device 100 is improved, and the bonding strength of the semiconductor device 100 may be also ensured.

In an example, the thermal conductivity of the above-mentioned second material is greater than or equal to 10 W/m*K.

For example, the thermal conductivity of the second material may be 10 W/m*K, 20 W/m*K, 30 W/m*K, 50 W/m*K, 100 W/m*K, or 120 W/m*K.

The overall thermal conductivity of the bonding dielectric layer 20 can be improved, thereby improving the heat dissipation capability of the semiconductor device 100.

In some examples, the above-mentioned second material comprises at least one of silicon nitride, aluminum oxide, and silicon carbide.

For example, the second material may comprise silicon nitride, aluminum oxide, or silicon carbide.

For another example, the second material may comprise silicon nitride and aluminum oxide, may also comprise silicon nitride and silicon carbide, and may also comprise aluminum oxide and silicon carbide, etc.

Thermal conductivity of a silicon nitride material is approximately 20 W/m*K, thermal conductivity of an aluminum oxide material is approximately 35 W/m*K, and thermal conductivity of a silicon carbide material is approximately 120 W/m*K. The second material comprising at least one of silicon nitride, aluminum oxide, and silicon carbide can result in high thermal conductivity of the bonding dielectric layer 20. In a process of transferring heat from the chip 10 to the bonding dielectric layer 20, the heat can be well conducted or diffused from the bonding dielectric layer 20 to the outside, thereby improving the heat dissipation capability of the chip 10 and the semiconductor device 100, and avoiding affecting the performance of the semiconductor device 100 due to the heat accumulation.

In an example, the first material comprises silicon oxide.

Thermal conductivity of a silicon oxide material is approximately 1.4 W/m*K. The silicon oxide material has good bonding performance.

The thermal conductivity of the first material is low, and the second material with the high thermal conductivity is added, such that the overall thermal conductivity of the bonding dielectric layer 20 is increased. After silicon oxide and the second material constitutes the bonding dielectric layer 20, it can be ensured that the bonding dielectric layer 20 has high bonding strength.

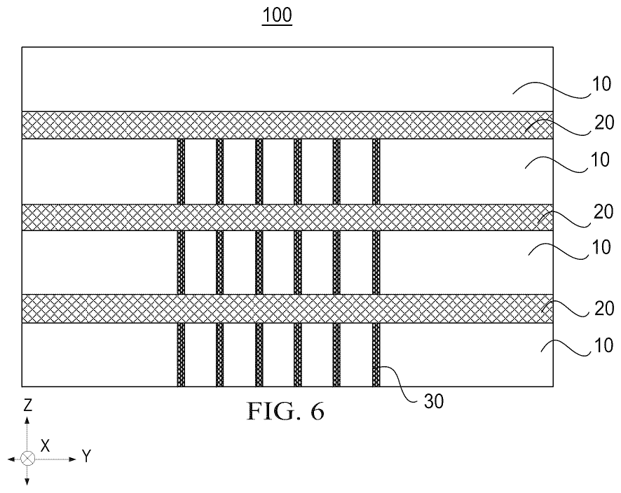

In some examples, as shown in FIG. 6, the semiconductor device 100 further comprises a plurality of conductive pillars 30 penetrating through the chips 10. The conductive pillars 30 are configured to connect the two adjacent ones of the chips 10.

For example, the conductive pillars 30 are filled within through Si vias (TSVs) penetrating through the chips 10. The conductive pillars 30 may comprise a metal material. The conductive pillars 30 further have a certain heat dissipation capability.

For example, each conductive pillar 30 only penetrates through one chip 10. In this case, the bonding of the two adjacent ones of the chips 10 in the semiconductor device 100 may be hybrid bonding.

The plurality of conductive pillars 30 described above may also serve as heat transfer channels for the semiconductor device 100 along the thickness direction of the chips 10, which is beneficial to improving the heat dissipation capability of the semiconductor device 100.

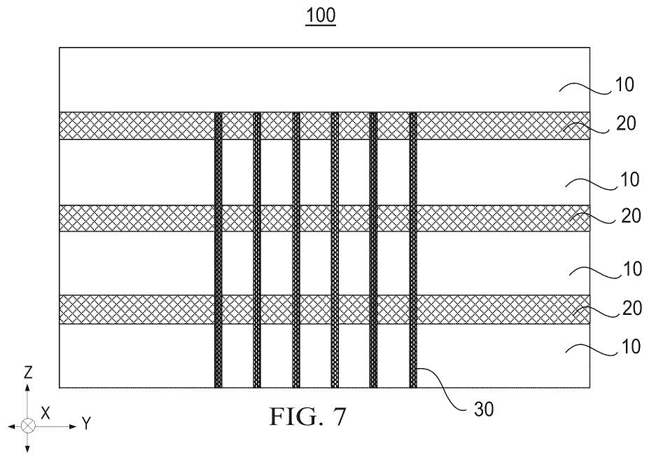

In some other examples, as shown in FIG. 7, the semiconductor device 100 further comprises: a plurality of conductive pillars 30 at least penetrating through the two adjacent ones of the chips 10 and the bonding dielectric layer 20 between the two adjacent ones of the chips 10. The conductive pillars 30 are configured to connect the two adjacent ones of the chips 10.

For example, one conductive pillar 30 may penetrate through the plurality of sequentially adjacent chips 10. In this case, the bonding of the two adjacent ones of the chips 10 in the semiconductor device 100 may be direct bonding.

The plurality of conductive pillars 30 described above may also serve as heat transfer channels for the semiconductor device 100 along the thickness direction of the chips 10, which is beneficial to improving the heat dissipation capability of the semiconductor device 100.

Furthermore, in the semiconductor device 100 shown in FIGS. 6 and 7, due to the arrangement of the bonding dielectric layer 20, the number of the conductive pillars 30 separately used for heat dissipation can be reduced to a certain extent, the distribution density of the conductive pillars 30 is reduced, and the fabrication cost and design difficulty of the semiconductor device 100 are reduced.

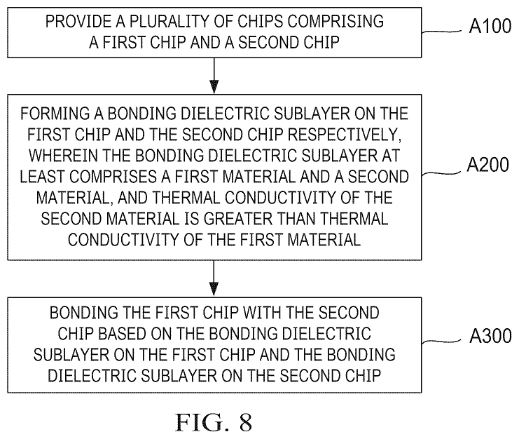

Some examples of the present disclosure further provide a fabrication method of a semiconductor device 100, which can be used for fabricating the semiconductor device 100 in the above-mentioned examples. FIG. 8 illustrates a flowchart of a fabrication method of a semiconductor device 100. The operations illustrated in FIG. 8 are not exclusive, and other operations may be performed as well before, after, or between any of the illustrated operations. Furthermore, some of the described operations may be performed simultaneously, or may be performed in a different order from that as shown in FIG. 8.

The following is an illustrative description of the above fabrication method in conjunction with the drawings. As shown in FIG. 8, the fabrication method comprises: A100-A300.

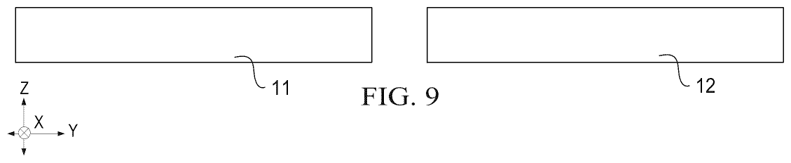

A100: As shown in FIG. 9, a plurality of chips 10 are provided. The plurality chips 10 comprise a first chip 11 and a second chip 12.

For example, sizes of the plurality of chips 10 may be equal or unequal.

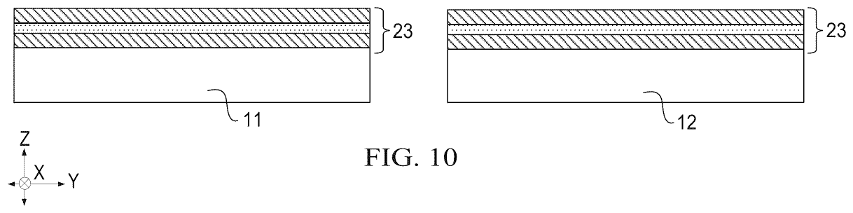

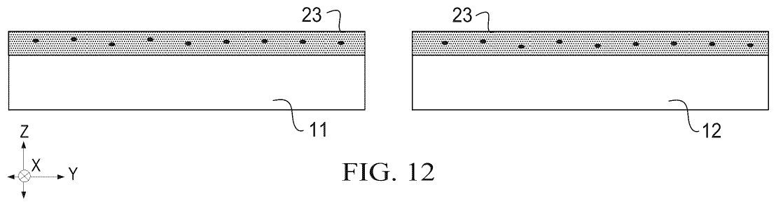

A200: As shown in FIG. 10 or 12, the bonding dielectric sublayer 23 are formed on the first chip 11 and the second chip 12 respectively. The bonding dielectric sublayer 23 at least comprises a first material and a second material, and thermal conductivity of the second material is greater than thermal conductivity of the first material.

For example, a structure of the bonding dielectric sublayer 23 on the first chip 11 may be the same as or different from a structure of the bonding dielectric sublayer 23 on the second chip 12.

For example, before forming the bonding dielectric sublayer 23, the chip 10 can be thinned, which is beneficial for the design of thinning the semiconductor device 100.

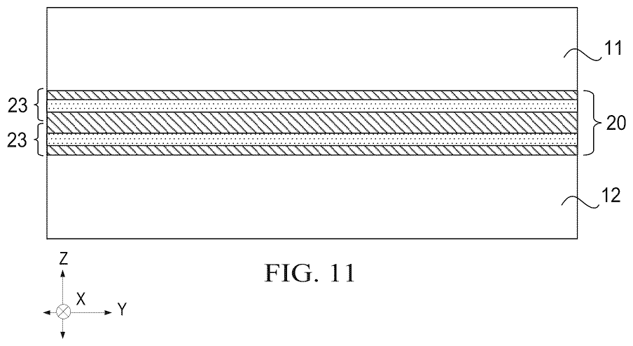

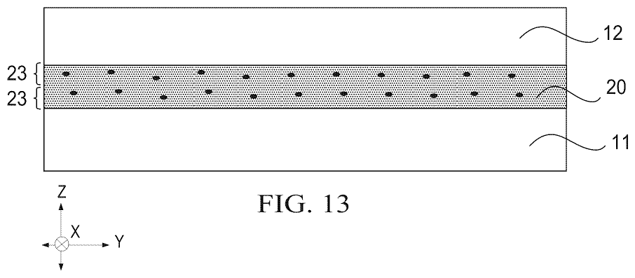

A300: As shown in FIG. 11 or 13, the first chip 11 and the second chip 12 are bonded based on the bonding dielectric sublayer 23 on the first chip 11 and the bonding dielectric sublayer 23 on the second chip 12.

For example, after the second chip 12 and the bonding dielectric sublayer 23 thereon are turned upside down, the bonding dielectric sublayer 23 on the first chip 11 and the bonding dielectric sublayer 23 on the second chip 12 are bonded to form the above-mentioned bonding dielectric layer 20.

According to the fabrication method of the semiconductor device 100 provided by the examples of the present disclosure, the bonding dielectric sublayer 23 is formed on the first chip 11 and the second chip 12, the bonding dielectric sublayer 23 at least comprises the first material and the second material, and the thermal conductivity of the second material is greater than the thermal conductivity of the first material; and the first chip 11 and the second chip 12 are bonded based on the bonding dielectric sublayer 23 to fabricate the semiconductor device 100, thereby utilizing the second material in the bonding dielectric sublayer 23 to result in high thermal conductivity of the bonding dielectric layer 20. The heat between the two adjacent ones of the chips 10 can be diffused and conducted to the outside in time through the second material with the high thermal conductivity, thereby improving the heat dissipation of the semiconductor device 100, and avoiding affecting the performance of the semiconductor device 100 due to the heat accumulation inside the chips 10.

There are various methods for forming the bonding dielectric sublayer 23, which can be selected according to actual needs. The examples of the present disclosure do not impose any limitations in this regard.

In some examples, in above-mentioned A200, forming the bonding dielectric sublayer 23 on the first chip 11 and the second chip 12 at least comprises: A210-A230.

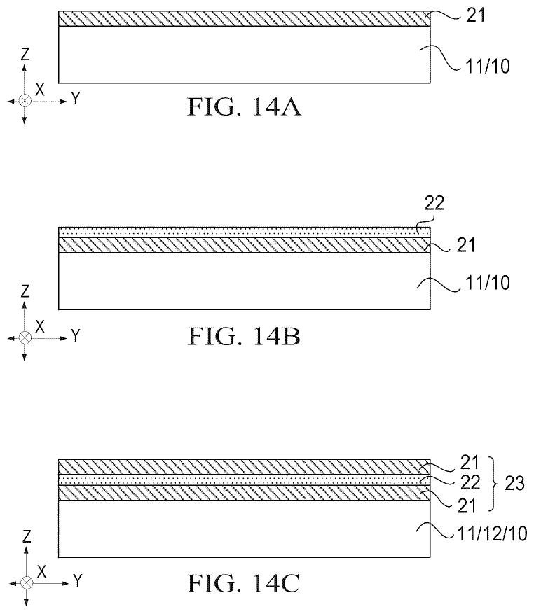

In A210, as shown in FIG. 14A, the first sublayers 21 are formed on the chips 10.

For example, a high density plasma chemical vapor deposition (HDP CVD for short) process can be used to form the first sublayers 21 on the chips 10. The first sublayer 21 may comprise the above-mentioned silicon oxide.

In A220, as shown in FIG. 14B, the second sublayers 22 are formed on the first sublayers 21.

For example, the high density plasma chemical vapor deposition process can be used to form the second sublayers 22 on the first sublayers 21. The second sublayer 22 may be the above-mentioned silicon nitride.

In A230, as shown in FIG. 14C, the first sublayers 21 are formed on the second sublayers 22.

Of course, it is also possible to continue to form the second sublayer 22, the first sublayer 21, the second sublayer 22, the first sublayer 21, etc. sequentially on the first sublayer 21.

By using the above-mentioned fabrication method, the formed bonding dielectric sublayer 23 comprises the plurality of first sublayers 21 and the plurality of second sublayers 22 sequentially stacked. The first sublayers 21 in the bonding dielectric sublayer 23 have a function of bonding, and the second sublayers 22 have good heat conduction, such that the heat dissipation capability of the semiconductor device 100 can be improved; and the formed bonding dielectric sublayer 23 extends along a direction perpendicular to the thickness direction of the chips 10, such that heat generated in the operation of the chips 10 and the semiconductor device 100 can be transferred and diffused in a lateral direction (the lateral direction may be referred to the first direction X and the second direction Y in FIG. 3) through the bonding dielectric layer 20, thereby increasing the number of dissipation paths for the heat, and further improving the heat dissipation capability of the semiconductor device 100.

The thicknesses of the above-mentioned first sublayers 21 and the second sublayers 22 may be referred to descriptions in some of the above examples of the present disclosure, which will not be repeated herein.

In some other examples, in above-mentioned A200, forming the bonding dielectric sublayer 23 on the first chip 11 and the second chip 12 comprises: forming the bonding dielectric sublayer 23 on the first chip 11 and the second chip 12 using a plasma enhanced chemical vapor deposition (PECVD for short) process. In the bonding dielectric sublayer 23, the second material is doped in the first material.

By using the above-mentioned fabrication method, the bonding dielectric sublayer 23 can not only have a function of bonding, but also have good heat conduction, thereby improving the heat dissipation capability of the semiconductor device 100.

For example, the above-mentioned second material may comprise silicon nitride, the first material may comprise silicon oxide, and silicon nitride is doped in silicon oxide.

Taking the second material comprising silicon nitride and the first material comprising silicon oxide as an example, a reaction gas for forming the bonding dielectric sublayer 23 comprises silane, nitrogen, and nitrous oxide.

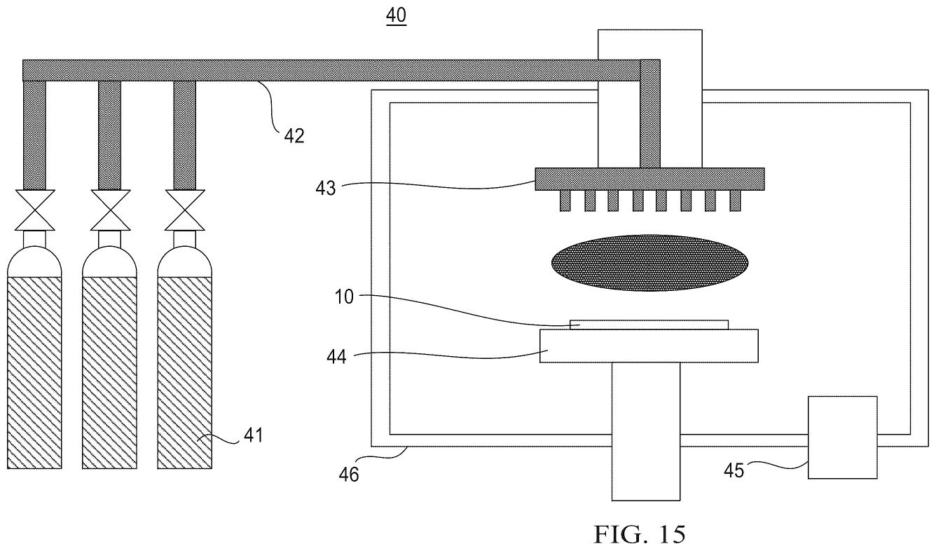

FIG. 15 illustrates a simple structural diagram of a plasma chemical vapor deposition equipment 40. The equipment comprises a plurality of gas cylinders 41, a gas intake system 42, an ionization part 43, a wafer tray 44, a vacuum pumping equipment 45, a reaction chamber 46, etc.

For example, the vacuum pumping equipment 45 can perform a vacuum pumping operation on the reaction chamber 46 and control the vacuum level within the reaction chamber 46. The reaction gas can be stored in the different gas cylinders 41, enter the ionization part 43 through the gas intake system 42, and then enter the reaction chamber 46 after being ionized. A chip 10 can be placed on the wafer tray 44.

The above-mentioned reaction gas can generate silicon oxide doped with silicon nitride within the reaction chamber 46, and silicon oxide doped with silicon nitride is deposited on a surface of the chip 10 to form a bonding dielectric sublayer 23.

By using the above-mentioned fabrication method, the fabrication of the bonding dielectric sublayer 23 can be simple and convenient, which is beneficial to simplifying the fabrication process.

The above descriptions are merely particular implementations of the present disclosure, and the protection scope of the present disclosure is not limited to those. Any variation or replacement that may be readily figured out by those skilled in the art within the technical scope disclosed by the present disclosure shall be encompassed within the protection scope of the present disclosure. The protection scope of the present disclosure shall be defined by the protection scope of the claims.

What is claimed is:

1. A semiconductor device, wherein the semiconductor device comprises:
chips stacked along a thickness direction of the chips; and
a bonding dielectric layer located between two adjacent ones of the chips, wherein the bonding dielectric layer at least comprises a first material and a second material, and thermal conductivity of the second material is greater than thermal conductivity of the first material.

2. The semiconductor device of claim 1, wherein the bonding dielectric layer extends along a direction perpendicular to the thickness direction of the chips.

3. The semiconductor device of claim 1, wherein the bonding dielectric layer comprises first sublayers and second sublayers alternately stacked along the thickness direction of the chips; and
the first sublayers comprise the first material, and the second sublayers comprise the second material.

4. The semiconductor device of claim 3, wherein in the bonding dielectric layer, each of the second sublayers is located between any two adjacent ones of the first sublayers.

5. The semiconductor device of claim 4, wherein in the bonding dielectric layer, a thickness of the first sublayer adjoining a chip of the chips is greater than or equal to a thickness of the second sublayer.

6. The semiconductor device of claim 4, wherein in the bonding dielectric layer, a thickness of the first sublayer located between two adjacent ones of the second sublayers is greater than or equal to a thickness of the first sublayer adjoining a chip of the chips.

7. The semiconductor device of claim 3, wherein in the bonding dielectric layer,
the first sublayer adjoining the chip is configured to achieve bonding between a chip of the chips and the second sublayer; and
the first sublayer located between two adjacent ones of the second sublayers is configured to achieve bonding between two adjacent ones of the chips.

8. The semiconductor device of claim 3, wherein a ratio of a sum of thicknesses of the second sublayers to a sum of thicknesses of the first sublayers has a range that is greater than or equal to 1:10, and less than or equal to 1:2.

9. The semiconductor device of claim 1, wherein in the bonding dielectric layer, the second material is doped in the first material.

10. The semiconductor device of claim 1, wherein the thermal conductivity of the second material is greater than or equal to 10 W/m*K.

11. The semiconductor device of claim 1, wherein the first material comprises a bonding material; and the second material comprises a heat conduction material.

12. The semiconductor device of claim 1, wherein the second material comprises at least one of silicon nitride, aluminum oxide, and silicon carbide.

13. The semiconductor device of claim 1, wherein the first material comprises silicon oxide.

14. The semiconductor device of claim 1, wherein the semiconductor device further comprises a plurality of conductive pillars penetrating through the chips, and each of the plurality of conductive pillars is configured to connect two adjacent ones of the chips.

15. The semiconductor device of claim 1, wherein the semiconductor device further comprises a plurality of conductive pillars at least penetrating through two adjacent ones of the chips and the bonding dielectric layer between the two adjacent ones of the chips, and each of the plurality of conductive pillars is configured to connect the two adjacent ones of the chips.

16. A fabrication method of a semiconductor device, wherein the fabrication method comprises:
providing chips comprising a first chip and a second chip;
forming a bonding dielectric sublayer on the first chip and the second chip respectively, wherein the bonding dielectric sublayer at least comprises a first material and a second material, and thermal conductivity of the second material is greater than thermal conductivity of the first material; and
bonding the first chip with the second chip based on the bonding dielectric sublayer on the first chip and the bonding dielectric sublayer on the second chip.

17. The fabrication method of claim 16, wherein forming the bonding dielectric sublayer on the first chip and the second chip at least comprises:
forming a first sublayer on each of the chips;
forming a second sublayer on the first sublayer; and
forming the first sublayer on the second sublayer.

18. The fabrication method of claim 16, wherein forming the bonding dielectric sublayer on the first chip and the second chip comprises:
forming the bonding dielectric sublayer on the first chip and the second chip using a plasma enhanced chemical vapor deposition process, wherein in the bonding dielectric sublayer, the second material is doped in the first material.

19. The fabrication method of claim 18, wherein a reaction gas for forming the bonding dielectric sublayer comprises silane, nitrogen, and nitrous oxide.

20. A memory system, comprising:
a semiconductor device comprising:
chips stacked along a thickness direction of the chips; and
a bonding dielectric layer located between two adjacent ones of the chips, wherein the bonding dielectric layer at least comprises a first material and a second material, and thermal conductivity of the second material is greater than thermal conductivity of the first material; and
a controller coupled to the semiconductor device and configured to control the semiconductor device to store data.
